(19) United States
(12) Patent Application Publication
(10) Pub. No.: US 2007/0224852 A1
(43) Pub. Date: Sep. 27, 2007

(54) Shielded electrical harness with an angled connector, and its method of fabrication

(75) Inventors: Pascal Gouzien, Bouc Bel Air (FR); Stephane Giraud, Gignac La Nerthe (FR)

Correspondence Address: YOUNG & THOMPSON, 745 SOUTH 23RD STREET, 2ND FLOOR, ARLINGTON, VA, 22202, US

(73) Assignee: EUROCOPTER, MARIGNANE CEDEX (FR)

(21) Appl. No.: 11/723,607

(22) Filed: Mar. 21, 2007

(30) Foreign Application Priority Data
Mar. 23, 2006 (FR) 06 02553

(51) Int. Cl. H05K 1/00

(52) U.S. Cl. 439/76.1

(57) ABSTRACT

A bundle includes wire segments forming a branch fitted with an angled coupling including:

a base having the ends of the wire segments fastened thereto;

an angled rigid casing surrounding the wire segments and having a first end providing for bearing against the base; and

a member for fastening the casing to the base with a mutual variable orientation;

the branch is protected by a shielding sheath secured to a second end of the casing; the bundle includes an abutment member secured to the portion of the wire segments extending inside the angled casing and co-operating with the angled casing to prevent the portion of the wire segments from leaving the casing; the portion of the wire segments is twisted in such a manner that the mutual orientation between the base and the casing can be modified without introducing harmful mechanical stresses in these wire segment portions.

The present invention relates to a shielded electrical harness having an angled connector, and to a method of fabricating such a harness.

### FIELD OF THE INVENTION

The technical field of the invention is that of fabricating electrical harnesses for fitting to rotorcraft.

### BACKGROUND OF THE INVENTION

Numerous electrical or optical bundle systems fitted with connectors have already been proposed.

U.S. Pat. No. 1,565,321 describes a flexible electrical cord comprising a fabric sheath and a flexible protective sleeve of rubber overmolded thereon.

U.S. Pat. No. 4,006,956 describes a wire-passing device for connecting a plug or a microphone to a cable having a plurality of conductors; the device comprises a disk pierced by an opening through which the cable extends, a heat-shrink sleeve surrounding the disk and a portion of the cable, and extending through an opening in the housing of the plug; the conductors are of a length such that they are not fully stretched, so that traction exerted on the cable leads to stress inside the housing of the plug rather than in the connections of the conductors to the plug.

U.S. Pat. No. 4,629,275 describes a device for making a connection between a cable and a connector, the device comprising a flexible tubular body made of braided non-metallic filaments; the body is secured to the cable by an adhesive heat-shrink sleeve and also to the connector in order to limit the stresses in the connection.

European patent No. 1 191 639 describes an angled connector fitted to a bundle of optical or electrical cables.

The present invention relates more particularly to a bundle or harness comprising a plurality of electrically conductive wire segments, each wire segment being coated in an electrically insulating material, the wire segments being grouped together to form a branch of the bundle that is fitted at its free end with an angled coupling comprising:

a base (or plug) having the ends of said wire segments of the branch of the bundle secured thereto;

an angled rigid casing (or duct) surrounding the wire segments and having a first end designed to bear against the base; and

a member for fastening the casing on the base with the mutual orientation therebetween being variable.

The invention applies to this type of bundle in which at least the branch fitted with the connector is protected by a shielding sheath or braid that is generally made of metal and not very deformable, and that is secured to a second end of the angled casing or duct.

The base is for plugging into a corresponding part of a complementary (second) connector belonging to a second bundle or to a piece of equipment, in order to provide electrical continuity between the pins of the two connectors.

For this purpose, the two connectors must be in alignment, and they must therefore extend with a certain determined mutual orientation.

In particular when the second connector forms part of equipment in a rotorcraft and/or is rigidly secured to a wall of the rotorcraft, mutual engagement of the connectors requires the angled connector of the bundle to be at an orientation that corresponds to that of the second connector; the rigidity of the shielded bundle can impede or prevent the angled connector it carries being oriented; in some configurations it is possible to loosen the member that fastens the casing to the base, change the mutual orientation of the casing and the base, and then retighten the fastener member; nevertheless, the amplitude of this change in orientation is limited; such a modification also runs the risk of subjecting one or more of the conductors to unacceptable levels of mechanical stress.

### OBJECTS AND SUMMARY OF THE INVENTION

That is the problem that the invention seeks to satisfy.

A particular object of the invention is to propose a shielded electrical harness fitted with an angled connector, and a method of fabricating it, that are improved and/or that remedy, at least in part, the shortcomings or drawbacks of known harnesses.

In an aspect of the invention, there is provided a harness or bundle having one or more abutment members secured to the wire segment portion extending inside the angled casing or duct, said abutment member(s) co-operating with the angled casing to prevent said wire segment portion from leaving the casing. In addition, this wire segment portion is twisted so that the mutual orientation of the base and the casing can be modified without introducing harmful mechanical stresses to these wire segment portions.

In another aspect of the invention, there is provided a method of fabricating such a harness, the method comprising the following steps:

fitting the portion of the wire segments extending inside the angled casing or duct with at least one abutment member suitable for co-operating with the angled casing in order to prevent said portion of the wire segments from leaving the casing;

twisting said wire portions extending between the abutment(s) and the base; for this purpose, the base is turned in a predetermined orientation that can subsequently be modified during assembly on a rotorcraft, such changes in orientation causing localized twisting of the wire segments between the abutment(s) and the base, without applying stress to said wire segments because of said wire segments possessing extra length; and then

securing the angled casing to the base by means of the fastener member forming part of the connector.

### BRIEF DESCRIPTION OF THE DRAWINGS

Other aspects, characteristics, and advantages of the invention appear from the following description which refers to the accompanying drawings and which relates, without any limiting character, to preferred embodiments of the invention.

FIGS. 1 to 6 shows successive steps in a method of fabricating a harness in accordance with the invention, the figures being diagrammatic fragmentary section views showing one end of a branch of a harness that is to be fitted with an angled connector, the section being in a plane containing the longitudinal axis (reference 32) of the wires in said branch.

FIG. 7 shows a harness of the invention obtained by the method.

### MORE DETAILED DESCRIPTION

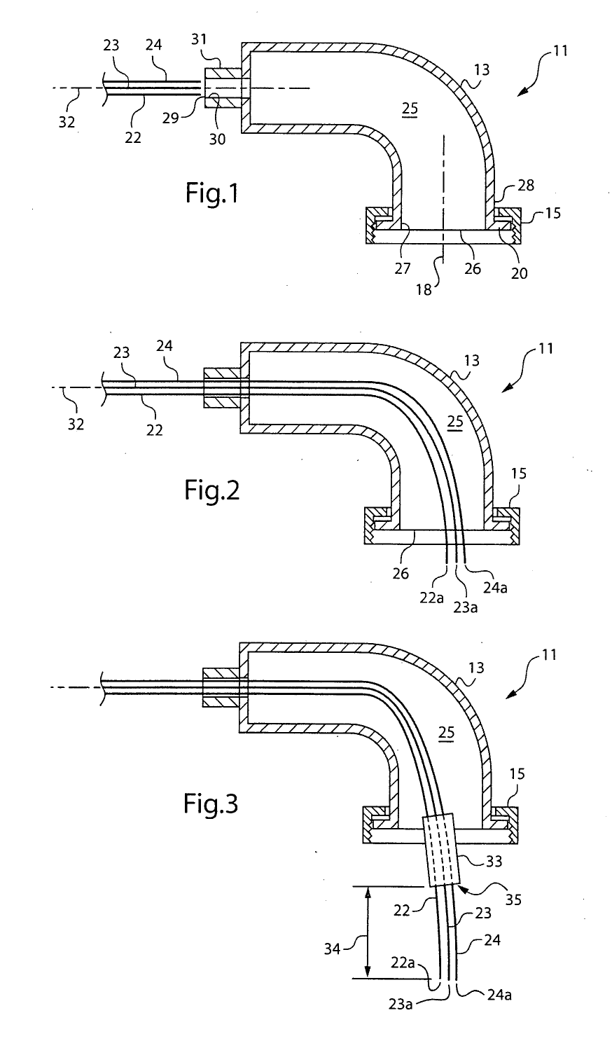

In FIGS. 1 to 7, the angled portion of the connector and the ring for securing to the base are shown diagrammatically in section view in order to reveal more clearly the components and the component portions that extend inside these two parts.

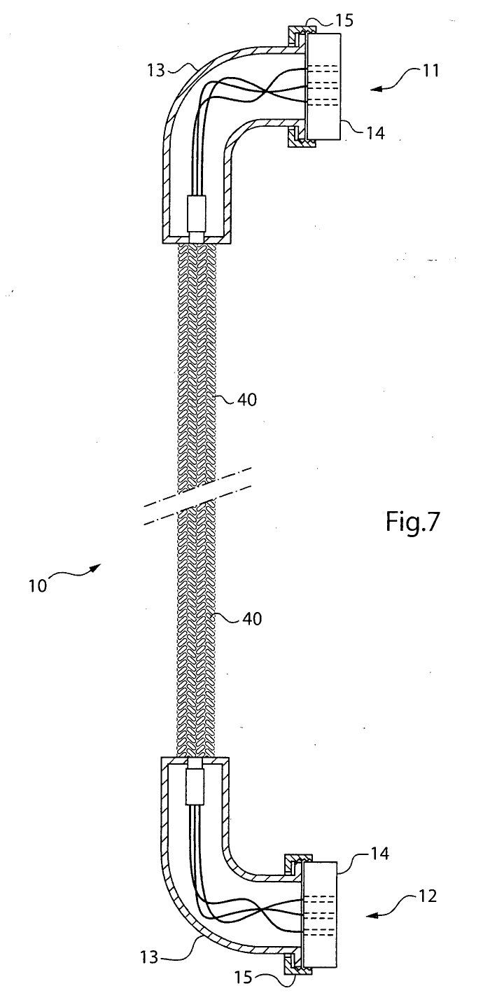

The harness 10 shown in FIG. 7 presents a single branch that is fitted at each of its two ends with an angled connector 11, 12 and that is provided with shielding 40.

The connector 11 in FIGS. 5 to 7 comprises an angled casing 13, a base 14, and a ring 15 serving to fasten the casing 13 to the base 14 in releasable manner.

For this purpose, the ring 15 presents a female thread 16 on its inside face that is designed to co-operate with a male thread of complementary shape and size that is provided on the outside face 17 of the base 14; the male thread is not shown in order to keep the figures clear; thus, this fastening is obtained by engaging the threaded portions in one another, and by causing the two parts 14 and 15 to turn relative to each other about an axis 18 corresponding substantially to an approximate axis of symmetry of these two parts.

During this screw fastening, a bearing surface 19 (in the form of an annular collar) of the ring 15 comes to bear against the complementary bearing surface 20 (likewise in the form of an annular collar) of the angled casing 13, until the part 13 is pressed by the collar 20 against the base 14.

The base 14 is pierced by three channels 21 (FIGS. 5 and 6), respectively for receiving the ends of three conductors 22 to 24 of the harness; these ends are secured, by crimping or soldering, for example, to pins (male or female) that are engaged in these channels 21.

As can be seen from FIG. 1 in particular, the casing 13 defines an angled cavity 25 that opens out firstly via a first opening 26 provided in a wall 27 situated at a first end 28 of the casing 13, and secondly via a second opening 29 provided in a wall 30 situated at a second end 31 of the casing 13.

In particular, the second end 31 is in the form of a cylindrical sleeve extending along an axis 32, and the first end is also in the form of a cylinder of axis 18, and it is terminated by the collar 20, the axes 18 and 32 generally being coplanar without being parallel (nor do they coincide).

With reference to FIGS. 1 and 6 in particular, fabrication of the harness comprises the following operations in succession:

i) introducing (FIG. 1) conductors 22 to 24 into the cavity 25 via the orifice 29 (second opening);

ii) continuing this introduction until the ends 22a, 23a, and 24a of the conductors leave the cavity 25 via the first opening 26 (FIG. 2);

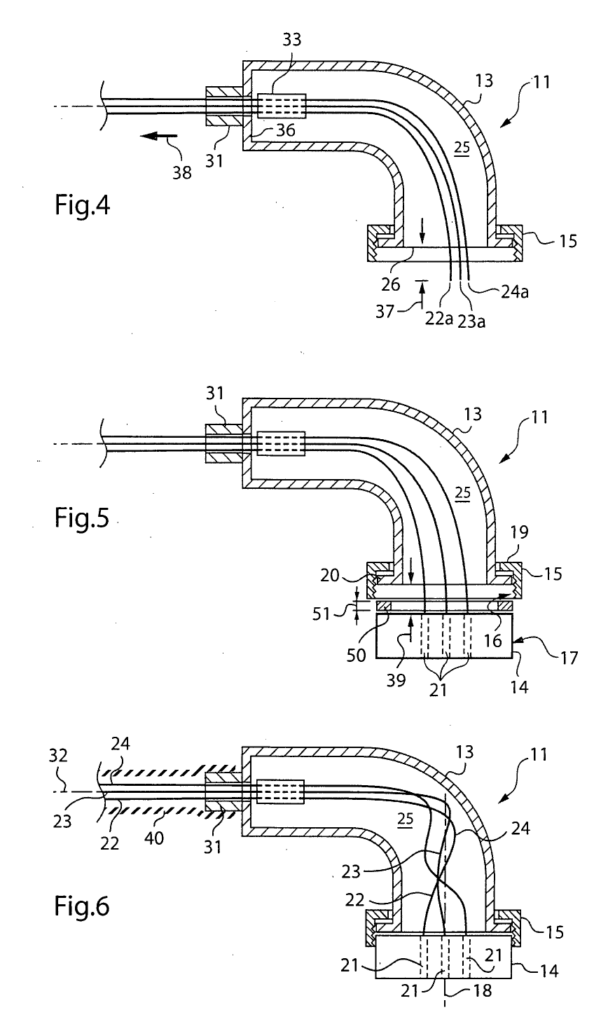

iii) engaging (FIG. 3) an adhesive tie 33 and/or a heat-shrink tubular sleeve around the conductors 22 to 24, and then tightening (FIG. 4) so as to tie these conductors together; this operation is performed while taking care to conserve a length 34 for the conductor wires 22 to 24, said length being measured between their ends 22a to 24a and the distal end 35 of the sleeve 33, that is sufficient to ensure that when the sleeve 33 is brought into abutment (FIG. 4) against a wall 36 of the end 31 of the casing 13, by sliding the conductors in the direction of arrow 38, the conductors presenting portions that project from the opening 26 by a length 37 that allows the ends 22a to 24a to be inserted into pins introduced into the channels 21 of the base 14 (FIG. 5), while retaining for these conductors, portions of length 39 (FIG. 5) that is sufficient to enable them to twist inside the cavity 25 after they have been fixed to the pins of the base, and without imparting any significant mechanical stress to the conductors;

iv) the ends 22a to 24a are secured to the pins fitted to the base 14, and then the conductors are pulled, along arrow 38, FIG. 4, until the sleeve 33 comes into abutment against the wall 36;

v) an annular spacer 50 of calibrated thickness 51 equal to the extra length 39 is introduced between the base 14 and the casing 13 while the braid is being put into place (following step) so as to guarantee that this extra length is complied with;

vi) an electromechanical shielding braid 40 surrounding the conductors 22 to 24 is then secured to the end 31 of the angled casing 13. By way of example, this connection can be made in the manner described in French patent No. 2 711 850 and U.S. Pat. No. 5,558,539;

vii) the spacer of calibrated thick-ness is withdrawn;

viii) the portions of wire extending between the sleeve and the base are twisted; this twisting can be performed in particular by causing the base 14 to turn with said ends 22a to 24a connected thereto about the axis 18 through an amplitude of about 90° to 180° or more, so that the base 14 has the same orientation as the second connector with which it is to be engaged; and

ix) the base 14 is secured to the casing 13 by screwing the ring 15.

Thus, the mutual orientation between the base 14 and the angled casing 13 can be modified at any time, by about plus or minus 90° to 180°.

For this purpose, it suffices to unscrew the ring 15 to separate the parts 13 and 14, which corresponds to the configuration shown in FIG. 5; thereafter, the mutual orientation is modified by causing the base 14 to turn relative to the casing 13 about the axis 18, through plus or minus 180°, for example; thereafter the connection ring 15 can be screwed back on.

During this change of orientation, the conductors are prevented from moving significantly relative to the end 31 of the casing 13 by the sleeve 33 bearing against the plane abutment 36.

What is claimed is:

1. A bundle (10) comprising a plurality of conductor wire segments (22 to 24) coated in an insulating material, the wire segments being grouped together to form a branch of the bundle that is fitted at its free end with an angled coupling comprising:
a base or plug (14) to which the ends (22a to 24a) of the wire segments of the branch of the bundle are secured;
an angled rigid casing or duct (13) surrounding the wire segments and having a first end (20, 28) designed to bear against the base; and
a member (15) for fastening the casing to the base with mutual orientation between them that is variable;
the branch being protected by a shielding sheath or braid (40) secured to a second end (30, 31) of the angled casing or duct, the bundle including one or more abutment members (33) secured to the portion of the wire segments that extend inside (25) the angled casing or duct and that adheres to at least one wire segment, said abutment member(s) co-operating with the angled casing or duct to prevent said portion of the wire segments from leaving said casing or duct, and wherein said portion of the wire segments presents an extra length (39) that enables localized twisting so that the mutual orientation between the base and the casing can be modified without introducing harmful mechanical stresses in these wire segment portions.

2. A bundle according to claim 1, in which the abutment member(s) comprise(s) a sleeve.

3. A bundle according to claim 2, in which the sleeve is a heat-shrink sleeve.

4. A bundle according to claim 1, in which the abutment member(s) surround(s) all of the wire segments.

5. A bundle according to claim 1, in which the twisting of the wires enables the mutual orientation between the base and the angled casing to be modified by at least about 90° to 180° approximately.

6. A bundle according to claim 1, in which the shielding sheath or braid (40) is made at least in part out of metal.

7. A bundle according to claim 1, in which the member (15) for fastening the casing to the base comprises a threaded ring.

8. A method of fabricating a harness or bundle according to claim 1, comprising the following steps:
fitting the portion of the wire segments extending inside the angled casing or duct with at least one abutment member suitable for co-operating with the angled casing in order to prevent said portion of the wire segments from leaving the casing;
twisting said wire portions extending between the abutment(s) and the base; for this purpose, the base is turned in a predetermined orientation that can subsequently be modified during assembly on a rotorcraft, such changes in orientation causing localized twisting of the wire segments between the abutment(s) and the base without applying stress to said wire segments because of said wire segments possessing an extra length (39); and then
securing the angled casing to the base by means of the fastener member forming part of the connector.

9. A method according to claim 8, in which an adhesive tie and/or a heat-shrink tubular sleeve is engaged around the conductors; the tie or sleeve is tightened in order to tie the conductors together while ensuring that a length (34) of the wires measured between their ends (22a to 24a) and the distal end (35) of the sleeve is sufficient to ensure that, when the sleeve is in abutment against a wall (36) at the end (31) of the casing (13), the conductors present portions projecting from the casing (13) of length (37) that enables the ends to be inserted into pins introduced in the channels (21) of the base, while conserving for these conductors, portions of a length (39) that is sufficient to enable them to be twisted by turning the base and then securing the base to the angled casing (13) in a position that can be modified in order to coincide with the position of a second connector.
